(19) United States
(12) Patent Application Publication
(10) Pub. No.: US 2021/0311097 A1
(43) Pub. Date: Oct. 7, 2021

(54) AUTOMATION ENGINEERING TWO-WIRE FIELD DEVICE

(71) Applicant: Endress+Hauser SE+Co. KG, Maulburg (DE)

(72) Inventors: Eric Schmitt, Steinsoultz (FR); Wolfgang Trunzer, Lörrach (DE)

(21) Appl. No.: 17/265,010

(22) PCT Filed: Jul. 31, 2019
(86) PCT No.: PCT/EP2019/070672

§ 371 Date: Feb. 1, 2021

(30) Foreign Application Priority Data
Aug. 1, 2018 (DE) 10 2018 118 706.8

(51) Int. Cl. G01R 19/165; H02J 1/06; G01D 18/00

(52) U.S. Cl. CPC G01R 19/16576; G01D 18/00; H02J 1/06

(57) ABSTRACT

An automation engineering two-wire field device, having: a sensor element for capturing a process variable; a connection terminal for connecting a two-wire line; field device electronics supplied with an operating power by a terminal voltage and a loop current from the two-wire line and configured to communicate the captured process variable by setting the loop current to a value between 4 mA and 20 mA; and a diagnosis unit configured so as, at least in the measurement mode, to capture at least one applicable value for the terminal voltage for each of at least two different values of the loop current set to between 4 mA and 20 mA, and to take exclusively the values captured in the measurement mode as a basis for making a statement about a minimum value of the terminal voltage for a maximum value of the loop current greater than 21 mA.

The invention relates to an automation engineering two-wire field device.

In automation engineering, in particular in process automation, field devices which serve for the determination, optimization and/or influencing of process variables are widely used. Sensors, such as fill-level measuring devices, flow meters, pressure and temperature measuring devices, pressure and temperature measuring devices, conductivity measuring devices, etc., are used for capturing the respective process variables, such as fill level, flow rate, pressure, temperature and conductivity. Actuators, such as, for example, valves or pumps, are used to influence process variables. The flow rate of a fluid in a pipeline section or a filling level in a container can thus be altered by means of actuators. Field devices, in general, refer to all devices which are process-oriented and which supply or process process-relevant information. In the context of the invention, field devices also refer to remote I/Os (electrical interfaces), radio adapters and/or, in general, devices that are arranged on the field level.

A variety of such field devices are manufactured and marketed by the Endress+Hauser company.

Currently, so-called two-wire field devices are also used in a multitude of existing automation systems. These are connected via a two-wire line, i.e. a line with two separately formed wires, to a higher-level unit, for example a PLC control unit or a control system. Two-wire field devices are designed here in such a way that measurement or control values as a main process variable are communicated, i.e. transmitted, in analog form via the two-wire line or two-wire cable as a 4-20 mA loop current or current signal. In this case, a loop current of the two-wire line is set to a specific value according to the captured process variable by the field device or the higher-level unit.

Especially the HART protocol, in which a frequency signal is superimposed on the analog current signal of 4-20 mA as a digital two-wire signal for data transmission, has proven successful for transmitting all other data. According to the HART protocol, there is a switch between 1200 Hz and 2400 Hz for data transmission, wherein the lower frequency stands for a logic “0” and the higher frequency for a logic “1.” In this way, the analog current signal, which changes only slowly, is unaffected by the frequency superposition, so that it is combined by means of HART analog and digital communication.

In addition to the data transmission, the two-wire line also serves to supply the two-wire field device. In this case, a field-device electronics unit, which is connected to the two-wire line via a connection terminal, is supplied with a power required for operation in the form of a terminal voltage, which is applied across the connection terminal and a loop current which is applied via the connection terminal.

At a low value of the loop current, for example at 4 mA, the terminal voltage generally has a value high enough for the minimum terminal voltage, so that error-free operation of the field device is ensured.

The error-free operation of the field device is more critical if the terminal voltage falls below a minimum value. This can be due, for example, to the fact that a communication resistor has been introduced into the two-wire line.

In order to detect a possible fall below the terminal voltage in good time and to be able to react thereto, there are already approaches of equipping two-wire field devices with corresponding diagnostic capabilities.

The object of the invention is therefore to propose an automation engineering two-wire field device having improved diagnostic capability.

The object is achieved according to the invention by the automation engineering two-wire field device according to claim 1.

The automation engineering two-wire field device according to the invention comprises:
a sensor element for capturing a process variable;
a connection terminal for connecting a two-wire line;
a field-device electronics unit, which field-device electronics unit is supplied by the two-wire line with an operating power via a terminal voltage, which is applied to the connection terminal, and a loop current, which flows through the connection terminal, and which field-device electronics unit is configured so as, in a measurement mode, to communicate the captured process variable via the two-wire line by setting the loop current at a value between 4 mA to 20 mA that represents the process variable;
a diagnosis unit configured to capture at least one corresponding value for the terminal voltage at least in the measurement mode at at least two different values of the loop current set between 4 mA to 20 mA and to make a statement on the basis of the values captured in the measurement mode about a minimum value of the terminal voltage at a maximum value of the loop current which is greater than 21 mA.

The advantage of a two-wire field device designed according to the invention is that, at any desired value of the loop current, whether the minimum value of the terminal voltage is sufficient even at a maximum value of the loop current to supply the field-device electronics unit can be ascertained. Furthermore, the two-wire field device designed in accordance with the invention offers the advantage that only values which have been captured in the measurement mode are used for the diagnosis, so that no “historical” data is required, which must be captured and stored, for example, in a separate setting or initializing operation.

An advantageous embodiment of the automation engineering two-wire field device provides that the diagnosis unit predicts the minimum value of the terminal voltage at the maximum value of the loop current and compares it to a minimum setpoint value for the terminal voltage in order to make a statement on the basis of the captured values for the terminal voltage and the corresponding values for the loop current. The embodiment can especially provide that the diagnosis unit is configured, in the event that the predicted minimum value of the terminal voltage is less than the minimum setpoint value for the terminal voltage, to make as a statement an undervoltage that is insufficient for supplying power to the field-device electronics unit and/or that the minimum setpoint value for the terminal voltage is in the range of from 9.5 to 11.5 V, preferably in the range of from 10 to 11 V, especially preferably approximately 10.5 V.

A further advantageous embodiment of the automation engineering two-wire field device provides that the maximum value of the loop current is in the range of 21-23 mA.

A further advantageous embodiment of the automation engineering two-wire field device provides that the diagnosis unit is configured to dynamically implement the at least two different values of the loop current and the respective at least one corresponding value for the terminal voltage and make the statement about the minimum value of the terminal voltage at the maximum value of the loop current. The embodiment can especially provide that, for dynamic implementation, the diagnosis unit is further configured to capture the at least two different values of the loop current and the respectively at least one corresponding value for the terminal voltage whenever two values of the loop current representing the captured process variable exceed a predetermined loop current differential value and/or that the predetermined loop current differential value is at least 1 mA.

A further advantageous embodiment of the automation engineering two-wire field device provides that the diagnosis unit determines a linear function on the basis of the at least two different values of the loop current and the respective at least one corresponding value for the terminal voltage and predicts or specifies the minimum value of the terminal voltage at the maximum value of the loop current using the linear function.

The invention is explained in more detail based upon the following drawings. The following is shown:

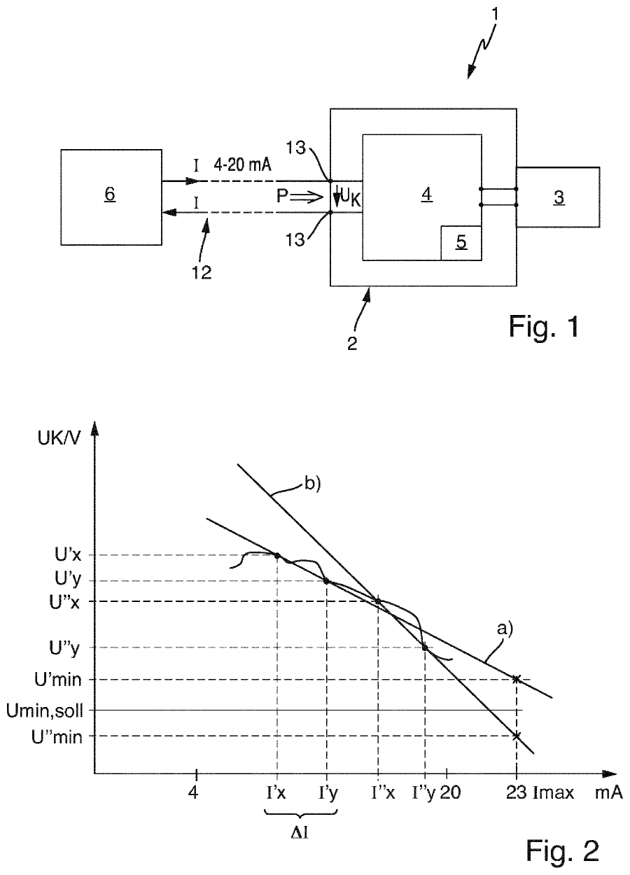

FIG. 1: a schematic representation of an automation engineering two-wire field device according to the invention, and

FIG. 2: a voltage-current diagram showing the terminal voltage in relation to the loop current.

FIG. 1 shows a schematic representation of the automation engineering two-wire field device according to the invention. The field device 1 comprises a preferably metallic housing 2 in which a field-device electronics unit 4 is arranged, and a sensor element 3 for capturing a process variable, for example a pressure measurement value. The two-wire field device 1 has a connection terminal 13 via which a two-wire line 12 with the two wires is electrically connected or connectible to the field-device electronics unit 4.

Via the two-wire line 12, the field-device electronics unit 4 and thus the field device 1 are connected to a higher-level unit or a control system, in order to communicate data by hard-wired connection with the higher-level unit. The measured values as a main process variable are thereby communicated analogously via the two-wire line 12 in the form of a 4-20 mA loop current signal by a corresponding current value of the 4-20 mA loop current being set by the field-device electronics unit 4 or a current regulator. In other words, the field-device electronics unit is configured to transmit the captured process variable to the higher-level unit by setting the loop current to a corresponding value in measurement mode.

Other data, which may include, for example, parameters of the field device, are transmitted in the form of a digital two-wire signal, for example, for example in accordance with the HART standard mentioned at the outset.

Furthermore, the field-device electronics unit 4 is supplied with power via the two-wire line or the 4-20 mA loop current. For this purpose, operating power is made available to the field-device electronics unit as a function of a terminal voltage UK, which is applied to the connection terminal, and the 4-20 mA loop current, which flows through the connection terminal. The terminal voltage UK preferably comprises a minimum voltage value of about 10 V and a minimum value for the loop current of about 3.6 mA, so that a minimum operating power results for the field-device electronics unit of Lmin=10 V*3.6 mA=36 mW. In principle, however, the values can also deviate therefrom, especially the terminal voltage UK can have a minimum value from the range of 10-30 V.

In order to ensure safe operation of the field device 1, a diagnosis unit 5 is also provided. As shown in FIG. 1, the diagnosis unit 5 can be designed as a part of the field-device electronics unit 4 or alternatively as a separate unit. The diagnosis unit 5 preferably has a computing unit, for example a microprocessor.

The diagnosis unit 5 is configured to carry out a voltage monitoring of the terminal voltage UK, in order to promptly detect whether a minimum setpoint value of the terminal voltage UK is undershot at a maximum value of the loop current, which is greater than 21 mA and preferably less than 23 mA, especially preferably approximately 22 mA. For this purpose, at least two different values Ix, Iy of the loop current I set between 4 to 20 mA, as well as the values corresponding thereto for the terminal voltage Ux, Uy, are captured by the diagnosis unit 5 in measurement mode, so that at least two value pairs Ix, Ux and Iy, Uy result. Preferably, the diagnosis unit 5 dynamically captures the values of the loop current Ix, Iy and the values of the corresponding terminal voltage Ux, Uy. This can be done, for example, by predetermining a loop current differential value ΔI for the diagnosis unit 5, and by the diagnosis unit 5 capturing the at least two different values of the loop current Ix, Iy whenever in measurement mode the two different values of the loop current Ix, Iy exceed the loop current differential value ΔI. This means that the two different values for the loop current Ix, Iy captured by the diagnosis unit 5 and the associated values for the terminal voltage Ux, Uy differ at least by the predefined differential value of the loop current ΔI. Preferably, the loop current differential value may be at least 1 mA. Furthermore, the loop current differential value ΔI may be set, for example, as a parameter by an operator of the field device 1 and stored in a memory of the field-device electronics unit 4. The diagnosis unit 5 is also configured to determine a linear function on the basis of the two different values for the loop current Ix, Iy and the associated values for the terminal voltage Ux, Uy and to predict or specify on the basis of the linear function the minimum value of the terminal voltage Umin, which would be present if the loop current I were set to a maximum (possible) value.

The two cases a) and b) are illustrated by way of example in FIG. 2. In case a), a linear function was determined by the diagnosis unit 5 on the basis of the two pairs of values (I′x, U′x) and (I′y, U′y) and the minimum value of the terminal voltage at a maximum or maximum possible value of the loop current of 23 mA was specified at U′min on the basis of the linear function. In case b), a linear function was determined by the diagnosis unit on the basis of the two value pairs I″x, U″x and I″y, U″y and the minimum value of the terminal voltage at a maximum or maximum possible value of the loop current of 23 mA was specified at U″min on the basis of the linear function.

The diagnosis unit 5 is further configured to compare the predicted or specified minimum value of the terminal voltage Umin to a minimum setpoint value for the terminal voltage Umin,soll, and, in the event that the minimum value of the terminal voltage Umin falls below the minimum setpoint value for the terminal voltage Umin, to ascertain an undervoltage which is not sufficient for fault-free operation of the field-device electronics unit 4. The ascertainment of the possible undershooting of the terminal voltage UK can furthermore be output by the diagnosis unit 5, for example in the form of an error message.

### LIST OF REFERENCE SIGNS

1 Field device
2 Field device housing
3 Sensor element
4 Field-device electronics unit
5 Diagnosis unit
6 Higher-level unit
12 Two-wire line or two-wire
13 Terminal
UK Terminal voltage
I Loop current
Ix, Iy Values of the loop current at specific points in time in the measurement mode of the field device
Ux, Uy Values of the terminal voltage at the values of the loop current Ix or Iy captured at specific points in time in the measurement mode of the field device
Umin Minimum value of terminal voltage that would be present if the loop current is set to a maximum value
Umin,soll Minimum necessary value of the terminal voltage which has to be applied to the connection terminal in order for the field-device electronics unit to be safely operated
Imax Maximum value to which the loop current is set, especially in the event of an error
ΔI Loop current differential value

1-9. (canceled)

10. An automation engineering two-wire field device, comprising:
a sensor element for capturing a process variable;
a connection terminal for connecting a two-wire line;
a field-device electronics unit, which is supplied with an operating power by a terminal voltage applied to the connection terminal and a loop current flowing through the connection terminal from the two-wire line, wherein the field-device electronics unit is configured to operate in a measurement mode, including communicating the captured process variable by setting the loop current to a value between 4 mA and 20 mA representing the captured process variable;
a diagnosis unit configured to operate in the measurement mode, including capturing a value for the terminal voltage for each of at least two different values of the loop current set to between 4 mA and 20 mA, and to take exclusively the values captured in the measurement mode as a basis for making a statement about a minimum value of the terminal voltage for a maximum value of the loop current greater than 21 mA.

11. The automation engineering two-wire field device according to claim 10, wherein the diagnosis unit, to take the captured values for the terminal voltage and the corresponding values for the loop current as a basis for making the statement, predicts the minimum value of the terminal voltage at the maximum value of the loop current and compares it to a minimum setpoint value for the terminal voltage.

12. The automation engineering two-wire field device according to claim 11, wherein the diagnosis unit is configured so as, in the event that the predicted minimum value of the terminal voltage is less than the minimum setpoint value for the terminal voltage, to take an undervoltage, which is not sufficient for supplying power to the field-device electronics unit, as a basis for making the statement.

13. The automation engineering two-wire field device according to claim 12, wherein the minimum setpoint value for the terminal voltage is in the range from 9.5 to 11.5 V.

14. The automation engineering two-wire field device according to claim 12, wherein the maximum value of the loop current is in the range of 21-23 mA.

15. The automation engineering two-wire field device according to claim 10, wherein the diagnosis unit is configured to dynamically execute the at least two different values of the loop current and the respective at least one corresponding value for the terminal voltage and make the statement about the minimum value of the terminal voltage at the maximum value of the loop current.

16. The automation engineering two-wire field device according to claim 15, wherein for dynamic performance the diagnosis unit is further configured to capture the at least two different values of the loop current and the respective at least one corresponding value for the terminal voltage whenever two values of the loop current representing the captured process variable exceed a predetermined loop current differential value in the measurement mode.

17. The automation engineering two-wire field device according to claim 16, wherein the predetermined loop current differential value is at least 1 mA.

18. The automation engineering two-wire field device according to claim 10, wherein the diagnosis unit determines a linear function on the basis of the at least two different values of the loop current and the respective at least one corresponding value for the terminal voltage and predicts or specifies the minimum value of the terminal voltage at the maximum value of the loop current on the basis of the linear function.
